(19) United States
(12) Patent Application Publication
(10) Pub. No.: US 2014/0159123 A1
(43) Pub. Date: Jun. 12, 2014

(54) ETCH RESISTANT RAISED ISOLATION FOR SEMICONDUCTOR DEVICES

(71) Applicant: INTERNATIONAL BUSINESS MACHINES CORPORATION, Armonk, NY (US)

(72) Inventors: Kangguo Cheng, Schenectady, NY (US); Balasubramanian S. Haran, Watervliet, NY (US); Shom Ponoth, Clifton Park, NY (US); Theodorus E. Standaert, Clifton Park, NY (US); Tenko Yamashita, Schenectady, NY (US)

(73) Assignee: INTERNATIONAL BUSINESS MACHINES CORPORATION, Armonk, NY (US)

(21) Appl. No.: 13/707,864

(22) Filed: Dec. 7, 2012

(51) Int. Cl. H01L 29/66; H01L 29/78

(52) U.S. Cl. CPC H01L 29/66477; H01L 29/78
USPC 257/288; 438/197

(57) ABSTRACT

A method including providing fins etched from a semiconductor substrate, the fins covered by an oxide layer and a nitride layer, the oxide layer located between the fins and the nitride layer, removing a portion of the fins to form an opening, and forming a spacer on a sidewall of the opening. The method further including filling the opening above the semiconductor substrate with a first fill material, where a top surface of the fill material is substantially flush with a top surface of the nitride layer, removing the spacer to expose a vertical sidewall of the first fill material, and depositing an encapsulation layer conformally on top of the first fill material, where the encapsulation layer is resistant to wet etching techniques and protects from the unwanted removal of the first fill material during subsequent process techniques.

### BACKGROUND

1. Field of the Invention

The present invention relates generally to the manufacture of integrated circuits, and more particularly to a structure and method to protect a raised isolation structure from wet etching during integration process flow.

2. Background of Invention

A raised isolation structure formed above the substrate and between one or more finFET devices may be used to electrically isolate adjacent devices. The raised isolation structure may be fabricated above the substrate in order to electrically isolate the finFET devices which are also formed above the substrate. Generally, the raised isolation structure may be formed from any suitable dielectric material such as oxide. In a typical integration, the raised isolation structure may be formed prior to the formation of the finFET devices. Raised isolation structures made from oxide may be susceptible to being removed during many wet and dry etching techniques commonly used during typical integration process flow of finFET devices. In such cases, there is a risk that the raised isolation structure may be damaged and compromise its ability to electrically isolate adjacent devices.

Therefore a need exists for a method to protect the raised isolation structure from being etched and compromised during subsequent processing techniques.

### SUMMARY

According to one embodiment of the present invention, a method is provided. The method may include providing a plurality of fins etched from a semiconductor substrate, the plurality of fins covered by an oxide layer and a nitride layer, the oxide layer located between the plurality of fins and the nitride layer, removing a portion of the plurality of fins to form an opening, and forming a spacer on a sidewall of the opening. The method may further include filling the opening above the semiconductor substrate with a first fill material, where a top surface of the fill material is substantially flush with a top surface of the nitride layer, removing the spacer to expose a vertical sidewall of the first fill material, and depositing an encapsulation layer conformally on top of the first fill material, where the encapsulation layer is resistant to wet etching techniques and protects from the unwanted removal of the first fill material during subsequent process techniques.

According to another exemplary embodiment, a structure is provided. The structure may include a first plurality of fins and a second plurality of fins etched from a semiconductor substrate, and an insulation structure positioned above the semiconductor substrate and between the first and second plurality of fins, where the insulation structure includes an encapsulation layer covering a vertical sidewall and a top of a fill material, and where the encapsulation layer is resistant to etching techniques designed to remove oxide.

### BRIEF DESCRIPTION OF THE SEVERAL VIEWS OF THE DRAWINGS

The following detailed description, given by way of example and not intended to limit the invention solely thereto, will best be appreciated in conjunction with the accompanying drawings, in which:

FIG. 1 illustrates a cross-sectional view of a finFET device at an intermediate step of its fabrication according to an exemplary embodiment.

FIG. 2 illustrates the removal of fins to form an isolation region according to an exemplary embodiment.

FIG. 3 illustrates the formation of a pair of spacers according to an exemplary embodiment.

FIG. 4 illustrates the deposition of a first fill material according to an exemplary embodiment.

FIG. 5 illustrates the removal of a portion of the first fill material according to an exemplary embodiment.

FIG. 6 illustrates the removal of the pair of spacers according to an exemplary embodiment.

FIG. 7 illustrates the deposition of an encapsulation layer according to an exemplary embodiment.

FIG. 8 illustrates the deposition of a second fill material according to an exemplary embodiment.

FIG. 9 illustrates the removal of a portion of the second fill material according to an exemplary embodiment.

FIG. 10 illustrates the removal of a nitride layer according to an exemplary embodiment.

FIG. 11 illustrates the removal of a portion of the encapsulation layer according to an exemplary embodiment.

FIG. 12 illustrates the removal of the second fill material according to an exemplary embodiment.

FIG. 13 illustrates the formation of a gate according to an exemplary embodiment.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

The invention relates to the manufacture of integrated circuits, and more particularly, to protecting raised isolation structures during integration process flows. The raised isolation structure may be susceptible to removal during common etching techniques used during typically integration process flows. As a result, the isolative properties of the raised isolation structure may be compromised, thereby risking the integrity of adjacent finFET devices.

A finFET device may include a plurality of fins formed in a wafer; a gate covering a portion of the fins, wherein the portion of the fins covered by the gate serves as a channel region of the device and portions of the fins extending out from under the gate serve as source and drain regions of the device; and dielectric spacers on opposite sides of the gate. The present embodiment may be implemented in a gate first or a gate last finFET integration process flow, however a gate last, or replacement gate (RG), process flow will be relied upon for the detailed description below.

In a RG process flow, a semiconductor substrate may be patterned and etched to form fins. Next, a dummy gate may be formed in a direction perpendicular to the length of the fins. For example, the dummy gate may be pattered and etched from a blanket layer of polysilicon. A pair of spacers can be disposed on opposite sidewalls of the dummy gate. Later, the dummy gate may be removed from between the pair of spacers, as by, for example, an anisotropic vertical etch process such as a reactive ion etch (RIE). This creates an opening between the spacers where a metal gate may then be formed. Typical integrated circuits may be divided into active areas and non-active areas. The active areas may include finFET devices.

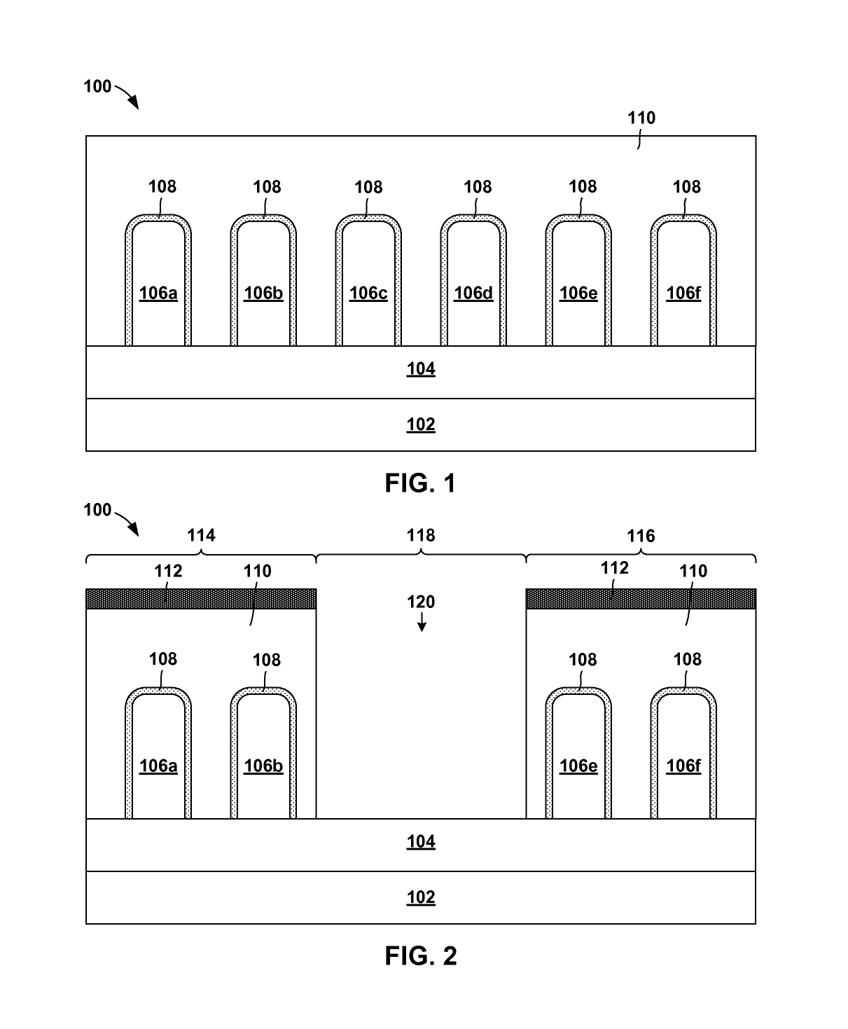

Referring now to FIGS. 1-12, exemplary process steps of forming a structure 100 in accordance with one embodiment of the present invention are shown, and will now be described in greater detail below. It should be noted that FIGS. 1-12 all represent a cross section view of wafer having a plurality of fins 106a-106f formed in a semiconductor substrate. The cross section view is oriented such that a view perpendicular to the length of the plurality of fins 106a-106f is depicted. Furthermore, it should be noted that while this description may refer to some components of the structure 100 in the singular tense, more than one component may be depicted throughout the figures and like components are labeled with like numerals. The specific number of fins depicted in the figures is for illustrative purposes only.

Referring now to FIG. 1, a cross section view of the structure 100 is shown at an intermediate step during the process flow. At this step of fabrication, the structure 100 may generally include the plurality of fins 106a-106f, etched from a substrate, having an oxide layer 108 and a nitride layer 110 deposited thereon.

The semiconductor substrate may include a bulk semiconductor or a layered semiconductor such as Si/SiGe, a silicon-on-insulator (SOI), or a SiGe-on-insulator (SGOI). Bulk semiconductor substrate materials may include undoped Si, n-doped Si, p-doped Si, single crystal Si, polycrystalline Si, amorphous Si, Ge, SiGe, SiC, SiGeC, Ga, GaAs, InAs, InP and all other III/V or II/VI compound semiconductors. In the embodiment shown in FIG. 1 a SOI substrate may be used. The SOI substrate may include a base substrate 102, a buried dielectric layer 104 formed on top of the base substrate 102, and a SOI layer (not shown) formed on top of the buried dielectric layer 104. The buried dielectric layer 104 may isolate the SOI layer from the base substrate 102. It should be noted that the plurality of fins 106a-106f may be etched from the uppermost layer of the SOI substrate, the SOI layer.

The base substrate 102 may be made from any of several known semiconductor materials such as, for example, silicon, germanium, silicon-germanium alloy, silicon carbide, silicon-germanium carbide alloy, and compound (e.g. III-V and II-VI) semiconductor materials. Non-limiting examples of compound semiconductor materials include gallium arsenide, indium arsenide, and indium phosphide. Typically the base substrate 102 may be about, but is not limited to, several hundred microns thick. For example, the base substrate 102 may have a thickness ranging from 0.5 mm to about 1.5 mm.

The buried dielectric layer 104 may include any of several dielectric materials, for example, oxides, nitrides and oxynitrides of silicon. The buried dielectric layer 104 may also include oxides, nitrides and oxynitrides of elements other than silicon. In addition, the buried dielectric layer 104 may include crystalline or non-crystalline dielectric material. Moreover, the buried dielectric layer 104 may be formed using any of several known methods, for example, thermal or plasma oxidation or nitridation methods, chemical vapor deposition methods, and physical vapor deposition methods. The buried dielectric layer 104 may have a thickness ranging from about 5 nm to about 200 nm. In one embodiment, the buried dielectric layer 104 may have a thickness ranging from about 150 nm to about 180 nm.

The SOI layer, for example the plurality of fins 106a-106f, may include any of the several semiconductor materials included in the base substrate 102. In general, the base substrate 102 and the SOI layer may include either identical or different semiconducting materials with respect to chemical composition, dopant concentration and crystallographic orientation. In one particular embodiment of the present invention, the base substrate 102 and the SOI layer include semiconducting materials that include at least different crystallographic orientations. Typically the base substrate 102 or the SOI layer include a {110} crystallographic orientation and the other of the base substrate 102 or the SOI layer includes a {100} crystallographic orientation. Typically, the SOI layer may include a thickness ranging from about 5 nm to about 100 nm. In one embodiment, the SOI layer may have a thickness ranging from about 25 nm to about 30 nm. Methods for forming the SOI layer are well known in the art. Non-limiting examples include SIMOX (Separation by Implantation of Oxygen), wafer bonding, and ELTRAN® (Epitaxial Layer TRANsfer). It may be understood by a person having ordinary skill in the art that the plurality of fins 106a-106f may be etched from the SOI layer. Because the plurality of fins 106a-106f may be etched from the SOI layer, they too may include any of the characteristics listed above for the SOI layer.

The oxide layer 108 may include a silicon oxide or a silicon oxynitride. In one embodiment, the oxide layer 108 can be formed, for example, by thermal or plasma conversion of a top surface of the SOI layer into a dielectric material such as silicon oxide or silicon oxynitride. In one embodiment, the oxide layer 108 can be formed by the deposition of silicon oxide or silicon oxynitride by chemical vapor deposition (CVD) or atomic layer deposition (ALD). The oxide layer 108 may have a thickness ranging from about 1 nm to about 10 nm, although a thickness less than 1 nm and greater than 10 nm may be acceptable. In one embodiment, the oxide layer 108 may be about 5 nm thick.

The nitride layer 110 may include any suitable insulating material such as, for example, silicon nitride. The nitride layer 110 may be formed using known conventional deposition techniques, for example, low-pressure chemical vapor deposition (LPCVD). In one embodiment, the nitride layer 110 may have a thickness ranging from about 5 nm to about 100 nm. In one embodiment, the nitride layer 110 may be about 50 nm thick.

Referring now to FIG. 2, a mask layer 112 may be applied above the structure 100 and used to form one or more active areas and one or more isolation regions, for example a first active area 114, a second active area 116, and an insulation region 118. The mask layer 112 can be a soft mask such as photoresist or a hardmask such as an oxide. The mask layer 112 may cover and protect the first and second active areas 114, 116 while the plurality of fins 106a-106f, the oxide layer 108, and the nitride layer 110 located in the insulation region 118 may be removed. The plurality of fins 106a-106f, the oxide layer 108, and the nitride layer 110 of the insulation region 118 may be removed using any suitable non-selective etching technique such as dry etch, wet etch, or combination of both. For example, a dry etching technique using a CₓF_{y} based etchant may be used to remove the plurality of fins 106a-106f, the oxide layer 108, and the nitride layer 110 from the insulation region 118. The preferred etching technique will remove the plurality of fins 106a-106f, the oxide layer 108, and the nitride layer 110 from the insulation region 118 using a single removal technique, and may produce a first opening 120. In one embodiment, the plurality of fins 106a-106f, the oxide layer 108, and the nitride layer 110 may be individually removed in alternate etching steps. Preferably, the mask layer 112 may be aligned such that a suitable amount of the nitride layer 110 remains on a sidewall of the plurality of fins 106a-106f located in the first and second active areas 114, 116.

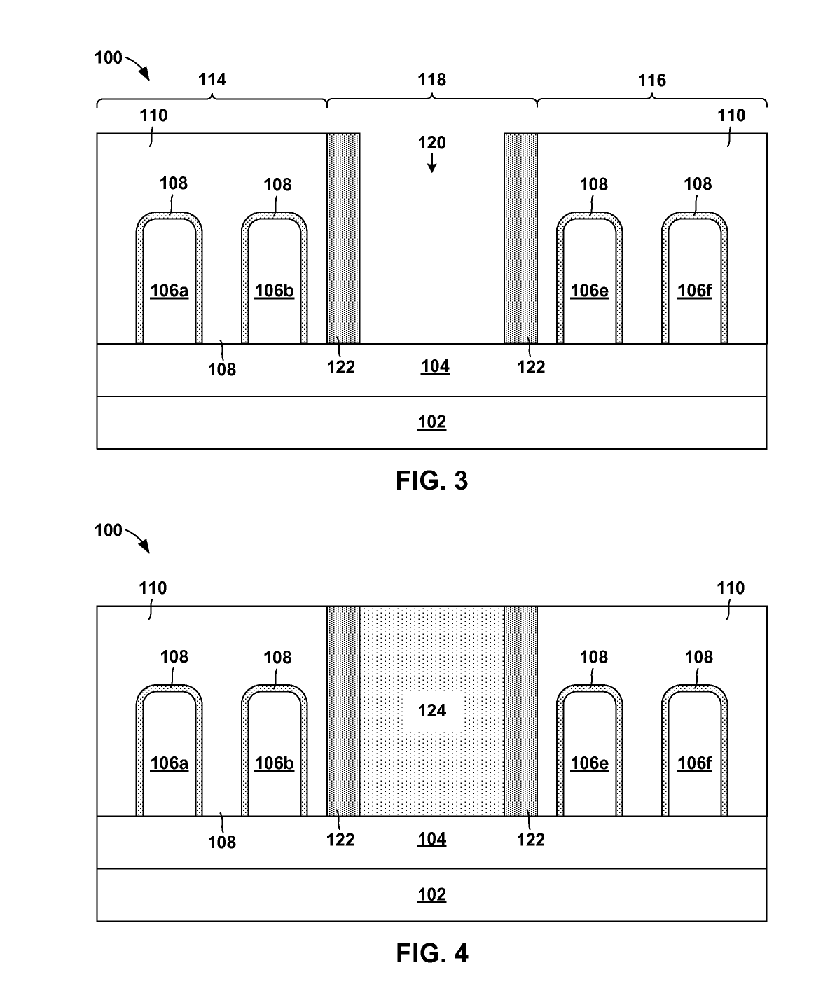

Referring now to FIG. 3, one or more spacers may be formed along the sidewalls of the first opening 120, for example a pair of spacers 122. The pair of spacers 122 may be formed by conformally depositing or growing any suitable spacer material, followed by a directional etch that removes the dielectric from the horizontal surfaces of the structure 100 while leaving it on the sidewalls of the first opening 120. In one embodiment, the pair of spacers 122 may be fabricated from amorphous silicon. In one embodiment, the pair of spacers 122 may have a horizontal width, or thickness, ranging from about 3 nm to about 30 nm, with 10 nm being most typical. Typically, the pair of spacers 122 may include a single layer; however, the pair of spacers 122 may include multiple layers of the same or different materials.

Referring now to FIG. 4, a first fill material 124 may be deposited within the first opening 120 using any suitable deposition technique known in the art. In one embodiment, the first fill material 124 may include any suitable oxide material know in the art. In one embodiment, the first fill material 124 may include a high aspect ratio oxide deposited using a CVD deposition technique. The first fill material 124 may have a thickness ranging from about 50 nm to about 1000 nm. In one embodiment, the first fill material 124 may have a thickness ranging from about 200 nm to about 600 nm. Preferably, the first fill material 124 may have a thickness greater than the height of the nitride layer 110. In one embodiment, the first fill material 124 can be a “weak” dielectric, such as flowable oxides, that normally would exhibit a high wet/dry etch rate in downstream modules.

After being deposited on top of the structure 100, the first fill material 124 may be planarized using a CMP technique. The CMP technique may remove some of the first fill material 124 selective to the nitride layer 110. In one embodiment, the CMP technique may use a ceria based slurry to polish the first fill material 124. The first fill material 124 will form a raised isolation structure.

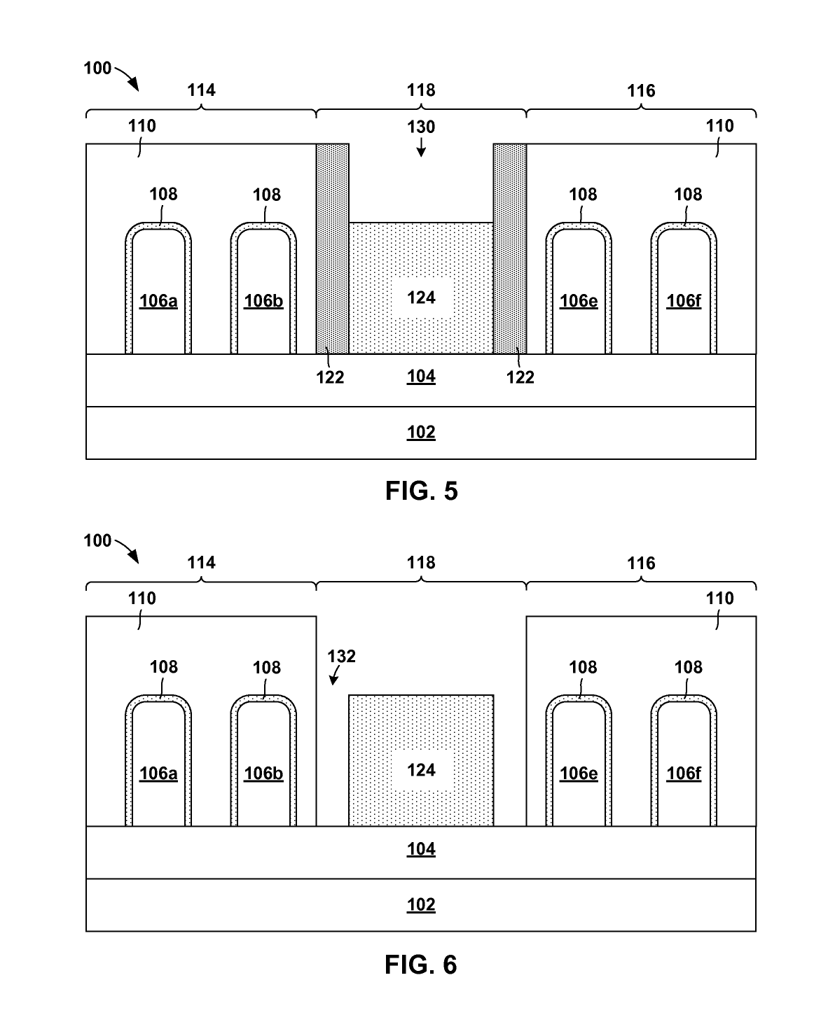

Referring now to FIG. 5, the first fill material 124 may be recessed to form a second opening 130. The first fill material 124 may be recessed selective to the nitride layer 110 and the pair of spacers 122 using any known etching technique suitable to remove oxide. In one embodiment, a wet etching technique using a hydrofluoric acid etchant may be used to recess the first fill material 124. The first fill material 124 may preferably be recessed to a level flush with a top surface of the plurality of fins 106a-106f. Because the recessed level of the first fill material 124 will dictate the final height of the raised isolation structure, it shall be recessed to a suitable level such that the resulting raised isolation structure provides a desired amount of isolation between adjacent semiconductor devices. In one embodiment, the first fill material 124 may be recessed to a level above the top surface of the plurality of fins 106a-106f.

Referring now to FIG. 6, the pair of spacers 122 may be selectively removed such that the nitride layer 110 and the first fill material 124 remain. In one embodiment, the selective removal may be accomplished by using any known etching technique suitable to remove amorphous silicon. In one embodiment, a wet etching technique using a room temperature SC1 solution (NH4 OH:H2 O2 :H2 O) may be used to remove the pair of spacers 122. Removal of the pair of spacer 122 will result in a gap 132 between the nitride layer 110 and the first fill material 124 such that a vertical sidewall of the first fill material 124 is exposed. The gap 132 may preferable extend from a top surface of the first fill material 124 down to the buried dielectric layer 104

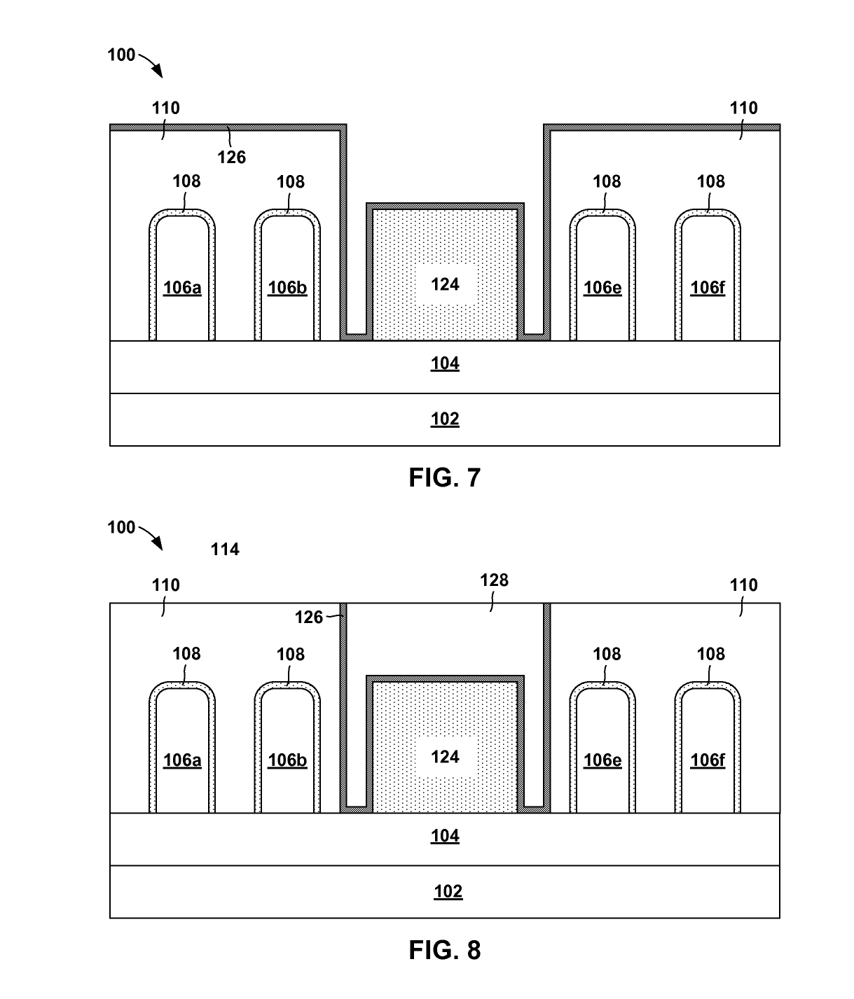

Referring now to FIG. 7, an encapsulation layer 126 may be conformally deposited on the structure 100, and more specifically directly on top of the first fill material 124, within the gap 132, and along the vertical sidewall of the first fill material 124. The encapsulation layer 126 may include any suitable material resistant to etching techniques designed to remove oxide, silicon, nitride, or low-k dielectric materials for example HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, a silicate thereof, and an alloy thereof. Each value of x is independently from 0.5 to 3 and each value of y is independently from 0 to 2. Other examples could be silicates including metal silicates and nitrided metal silicates. The encapsulation layer 126 may be formed using known conventional deposition techniques, for example, physical vapor deposition (PVD), atomic layer deposition (ALD), of chemical vapor deposition (CVD). In one embodiment, for example, the encapsulation layer 126 may include hafnium oxide deposited using an ALD deposition technique. The encapsulation layer 126 may have a thickness ranging from about 1 nm to about 20 nm. In one embodiment, the encapsulation layer 126 may have a thickness ranging from about 1 nm to about 5 nm. The encapsulation layer 126 may protect the first fill material 124 from unwanted erosion during downstream processes. Therefore, dielectric materials not otherwise considered due to their high etch rates may be used. The present embodiment therefore opens up possibilities for dielectrics that normally may not have been acceptable, such as flowables oxides, as mentioned above.

Referring now to FIG. 8, a second fill material 128 may be deposited directly on top of the encapsulation layer 126 using any suitable deposition technique known in the art. In one embodiment, the second fill material 128 may include any suitable oxide material know in the art. In one embodiment, the second fill material 128 may include the same or a different material as the first fill material 128. In one embodiment, the second fill material 128 may include a high aspect ratio oxide deposited using a CVD deposition technique. In one embodiment, the second fill material 128 may include organic films other than oxides. The second fill material 128 may have a thickness ranging from about 5 nm to about 200 nm. Preferably, the second fill material 128 may have a thickness such that it extends above and covers the nitride layer 110. The second fill material 128 may preferably protect the encapsulation layer 126 during subsequent processing.

After being deposited on top of the encapsulation layer 126, the second fill material 128 and the encapsulation layer 126 may be polished using a CMP technique. The CMP technique may remove some of the second fill material 128 and some of the encapsulation layer 126 selective to the nitride layer 110. In one embodiment, the CMP technique may use a ceria based slurry to polish the second fill material 128 and the encapsulation layer 126.

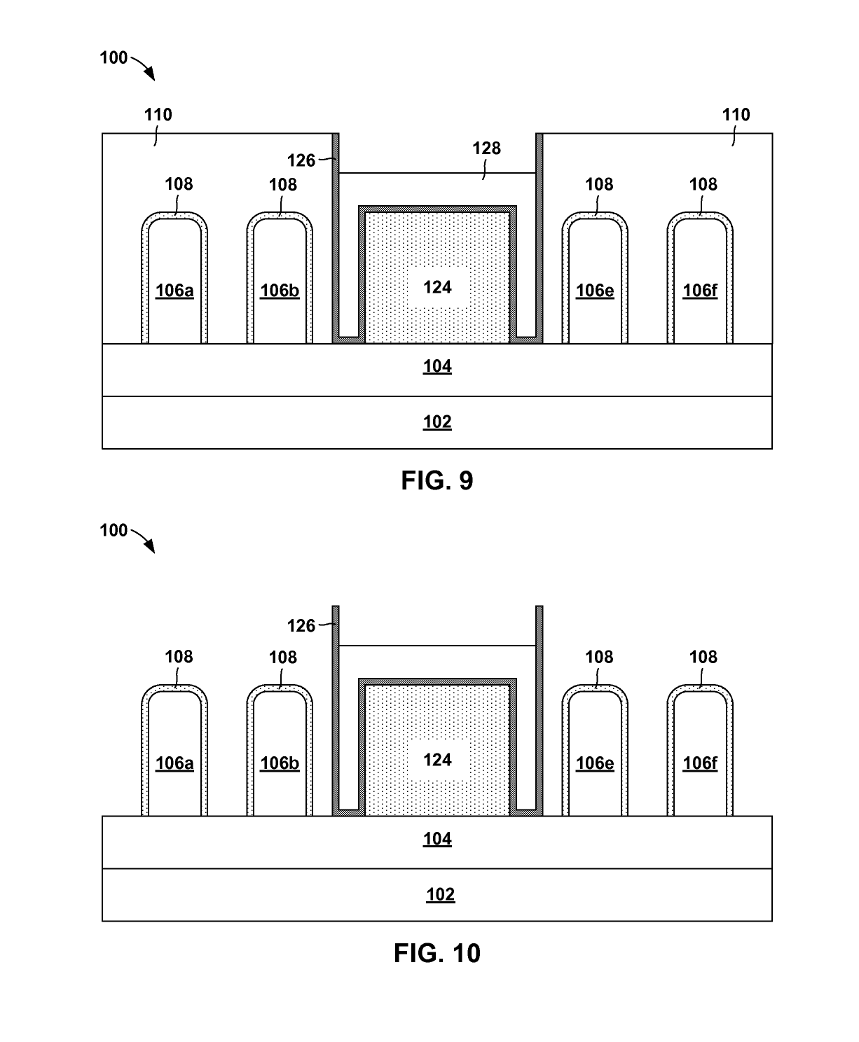

Referring now to FIG. 9, the structure 100 may undergo a deglaze technique prior to a selective nitride etch, described below with reference to FIG. 10. The deglaze technique may be used ensure no stray substance blocks the selective nitride etch. Some of the second fill material 128 may be consumed during the deglaze technique. Any suitable deglazing technique known in the art may be used. In one embodiment, a known chemical oxide removal (COR) etching technique may be used. The COR technique used may include exposing the structure 100 to a gaseous mixture of HF and ammonia, preferably in a ratio of 2:1, at a pressure between 1 mTorr and 10 mTorr and a temperature of about 25° C. During this exposure, the HF and ammonia gases react with the fill material 128 to form a solid reaction product. The solid reaction product may be subsequently removed by heating the structure to a temperature of about 100° C., thus causing the reaction product to evaporate. Alternatively, the reaction product may be removed by rinsing the structure 100 in water, or removing it with an aqueous solution. The second fill material 128 may preferably be recessed about 1 nm to about 15 nm, but preferably not expose the encapsulation layer 126. Therefore, removal of some of the second fill material 128 during the deglaze technique should be taken into consideration when a preferable recess depth of the first fill material 124 is chosen.

Referring now to FIG. 10, the nitride layer 110 may be selectively removed such that the oxide layer 108, the second fill material 128, and the encapsulation layer 126 remain. The selective removal may be accomplished by using any known etching technique suitable to remove nitride selective to oxide. In one embodiment, a hydrofluoric acid deglaze followed by a wet etching technique using a hot phosphorous etchant may be used to remove the nitride layer 110. Removal of the nitride layer 110 may result in an upper portion of the encapsulation layer 126 to be exposed on all sides and extend vertically above the second fill material 128.

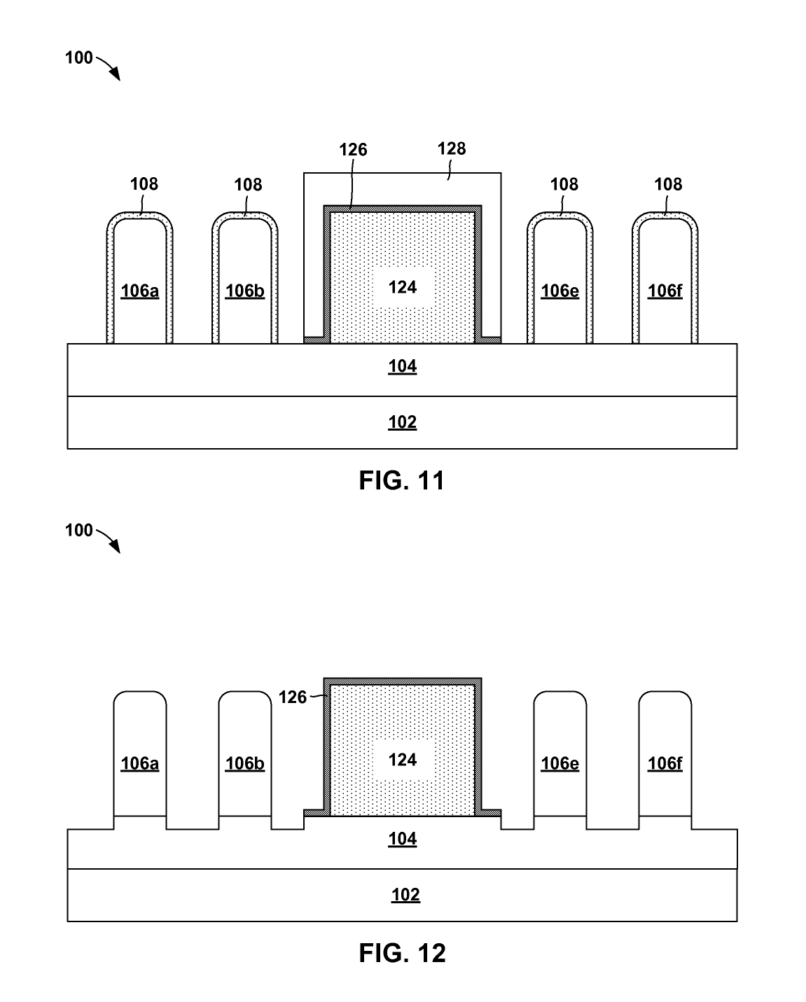

Referring now to FIG. 11, the exposed portion of the encapsulation layer 126, extending vertically from the buried dielectric layer 104 to above the second fill material 128, may be removed selective to the oxide layer 108 and the second fill material 128 using any etching technique suitable to remove hafnium oxide. In one embodiment, a known dry etching technique may be used to remove the exposed portion of the encapsulation layer 126. In one embodiment, the dry etching technique used may include a chlorine based etch chemistry such as BCL3, and a high chuck temperature ranging from about 100° C. to about 200° C.. In a preferred embodiment, all of the exposed portion of the encapsulation layer 126 is removed. Therefore, a portion of the encapsulation layer 126 located between the first fill material 124 and the second fill material 128 may remain.

Referring now to FIG. 12, next, the second fill material 128 and the oxide layer 108 may be removed using any suitable etching technique known in the art. In one embodiment, a known chemical oxide removal (COR) etching technique, as described above, may be used to remove the second fill material 128. Both the second fill material 128 and the oxide layer 108 may preferably be removed in their entirety.

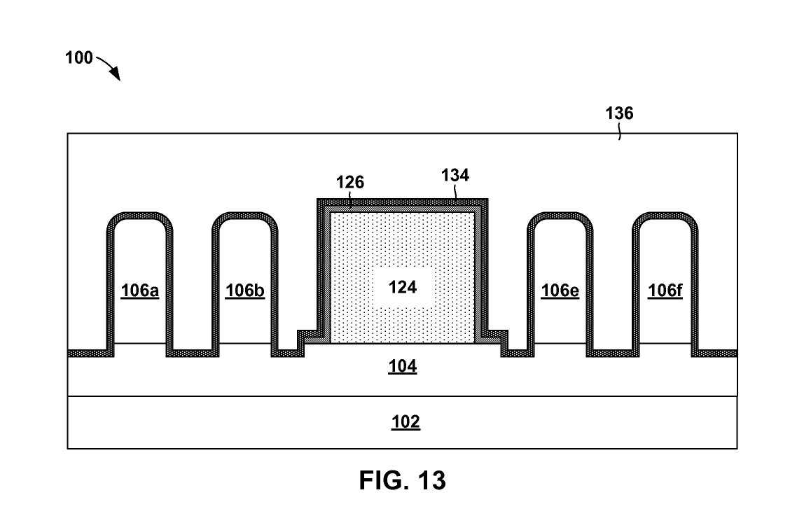

Referring now to FIG. 13, next, in a RG process flow a gate may be formed on the structure 100, and typical fabrication techniques may be used to complete the formation of the semiconductor devices. The RG process flow may include the formation of a gate oxide 134, or in some cases a dummy gate oxide, and a dummy gate material 136. In most cases the dummy gate material 136 may be sacrificial and replaced in a subsequent operation. In some cases the gate oxide 134 may be sacrificial, for example the dummy gate oxide, and replaced in a subsequent operation.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable others of ordinary skill in the art to understand the embodiments disclosed herein.

1-10. (canceled)

11. A structure comprising:
an insulation structure positioned above a portion of a semiconductor substrate and between a first plurality of fins and a second plurality of fins, the insulation structure electrically isolates the first plurality of fins from the second plurality of fins, wherein the insulation structure comprises:
a fill material in direct contact with and extending upwardly from an upper surface of the semiconductor substrate, the fill material comprises a height equal to or greater than a height of any one of the first or the second plurality of fins; and
an encapsulation layer on top of and completely covering the fill material, the encapsulation layer is resistant to etching techniques designed to remove an oxide.

12. The structure of claim 11, wherein the encapsulation layer comprises HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓ,N_{y}, LaAlOₓN_{y}, Y₂OₓN_{y}, a silicate thereof, or an alloy thereof, wherein each value of x is independently from 0.5 to 3 and each value of y is independently from 0 to 2.

13. The structure of claim 11, wherein the fill material comprises an oxide.

14. The structure of claim 11, wherein the encapsulation layer comprises hafnium oxide.

15. The structure of claim 11, wherein the semiconductor substrate comprises a buried dielectric layer, and the fill material is in direct contact with and extends upwardly from an upper surface of the buried dielectric layer.

16. The structure of claim 11, further comprising:
a gate above the first plurality of fins, above the second plurality of fins, and above the insulation structure, the gate separates the insulation structure from both the first plurality of fins and the second plurality of fins.

17. The structure of claim 11, wherein the fill material comprises a flowable oxide.

18. The structure of claim 11, further comprising;
a first active area comprising the first plurality of fins; and
a second active area comprising the second plurality of fins.

19. A structure comprising:
a raised isolation structure located above a portion of a semiconductor substrate and between a first plurality of fins and a second plurality of fins, the raised isolation structure electrically insulates the first plurality of fins from the second plurality of fins, the raised isolation structure is separated from and does not contact any one of the first or the second plurality of fins, the raised insolation structure comprises:
an inner core in direct contact with and extending upwardly from an upper surface of the semiconductor substrate, the inner core comprises a height equal to or greater than any one of the first or the second plurality of fins; and
an outer layer on top of and covering the inner core, the outer layer is resistant to etching techniques designed to remove an oxide.

20. The structure of claim 19, wherein the inner core comprises an oxide.

21. The structure of claim 19, wherein the inner core comprises a flowable oxide.

22. The structure of claim 19, wherein the outer layer comprises hafnium oxide.

23. The structure of claim 19, wherein the semiconductor substrate comprises a buried dielectric layer, and the inner core is in direct contact with and extends upwardly from an upper surface of the buried dielectric layer.

24. The structure of claim 19, further comprising;
a first active area comprising the first plurality of fins; and
a second active area comprising the second plurality of fins.

25. A structure comprising:
a raised isolation structure located above a semiconductor substrate and between a first active area and second active area, the raised isolation structure electrically insulating the first active region from the second active region, the raised isolation structure is separated from and does not contact the first active region or the second active region, the raised isolation structure comprises:
an inner core in direct contact with and extending upwardly from an upper surface of the semiconductor substrate, the inner core comprises a height equal to or greater than either the first or the second active regions; and
an outer layer on top of and covering the inner core, the outer layer is resistant to etching techniques designed to remove an oxide.

26. The structure of claim 25, wherein the inner core comprises an oxide.

27. The structure of claim 25, wherein the inner core comprises a flowable oxide.

28. The structure of claim 25, wherein the outer layer comprises hafnium oxide.

29. The structure of claim 25, wherein the semiconductor substrate comprises a semiconductor-on-insulator substrate, and the inner core is in direct contact with and extends upwardly from an upper surface of a buried dielectric layer of the semiconductor-on-insulator substrate.
